(19) United States
(12) Patent Application Publication
(10) Pub. No.: US 2023/0327017 A1
(43) Pub. Date: Oct. 12, 2023

(54) SILICON CARBIDE SEMICONDUCTOR DEVICE

(71) Applicant: FUJI ELECTRIC CO., LTD., Kawasaki-shi (JP)

(72) Inventors: Masakazu BABA, Matsumoto-city (JP); Shinsuke HARADA, Tsukuba-city (JP)

(73) Assignee: FUJI ELECTRIC CO., LTD., Kawasaki-shi (JP)

(21) Appl. No.: 18/176,113

(22) Filed: Feb. 28, 2023

(30) Foreign Application Priority Data
Mar. 22, 2022 (JP) 2022-044876

(51) Int. Cl. H01L 29/78; H01L 29/16; H01L 29/66

(52) U.S. Cl. CPC H01L 29/7813; H01L 29/1608; H01L 29/66068; H01L 29/66734; H01L 29/7811

(57) ABSTRACT

A silicon carbide semiconductor device includes a parallel pn layer that includes a standard portion and first and second portions. The standard portion is located at a center of the parallel pn layer in a depth direction and charge balanced. The first and second portions are respectively located closer to the first and second main surfaces than is the standard portion. In the first portion, an amount of a second-conductivity-type charge is greater than that of the first-conductivity-type regions, and continuously increases with a first gradient in a first direction from the standard portion toward the first main surface. In the second portion, an amount of charge of the first-conductivity-type regions is greater than that of the second-conductivity-type regions, and the amount of charge of the second-conductivity-type regions continuously decreases with a second gradient in a second direction from the standard portion toward the second main surface.

### CROSS REFERENCE TO RELATED APPLICATIONS

This application is based upon and claims the benefit of priority of the prior Japanese Patent Application No. 2022-044876, filed on Mar. 22, 2022, the entire contents of which are incorporated herein by reference.

### BACKGROUND OF THE INVENTION

### 1. Field of the Invention

Embodiments of the invention relate to a silicon carbide semiconductor device.

### 2. Description of the Related Art

A semiconductor device that has a superjunction (SJ) structure in which a drift layer is a parallel pn layer in which n-type regions and p-type regions are disposed adjacent to one another so as to repeatedly alternate with one another in a direction parallel to a main surface of a substrate is conventionally known. A semiconductor device having a SJ structure containing silicon (Si) as a semiconductor material has been disclosed in which an amount of charges in the n-type regions and an amount of charges in the p-type regions adjacent to one another in a parallel pn layer are varied to have a gradient in a depth direction (the charge balance is varied in the depth direction), whereby a breakdown voltage margin may be increased (for example, refer to Tamaki, T., et al, “Vertical Charge Imbalance Effect on 600 V-class Trench-filling Superjunction Power MOSFETs”, 2011 IEEE 23rd International Symposium on Power Semiconductor Devices & ICs:2011 ISPSD, USA, Institute of Electrical and Electronics Engineers (IEEE), May 2011, p.308-311).

Tamaki, T., et al, “Vertical Charge Imbalance Effect on 600 V-class Trench-filling Superjunction Power MOSFETs” discloses that a trench embedding epitaxial method is used to form the SJ structure by forming trenches (hereinafter, SJ trenches) in an n-type epitaxial layer, leaving portions that form the n-type regions of the parallel pn layer, and embedding the SJ trenches with a p-type epitaxial layer that forms the p-type regions of the parallel pn layer, so that the SJ trenches have, in a cross-sectional view, a tapered shape in which the width of each of the SJ trenches decreases as the depth of the SJ trenches increases, whereby the charge imbalance between the n-type regions and the p-type regions adjacent to one another in the parallel pn layer is created, i.e., a total amount of charges in the n-type region and the p-type region has a gradient in the depth direction.

The charge balance is an index that indicates the degree of equilibrium between: an amount of charge expressed by a product obtained by multiplying the carrier concentration (impurity concentration) and the width of the n-type regions of the parallel pn layer, and an amount of charge expressed by a product obtained by multiplying the carrier concentration and the width of the p-type regions of the parallel pn layer. To give the charge balance of the n-type regions and the p-type regions adjacent to one another in the parallel pn layer a gradient in the depth direction, there is a method of varying the impurity concentration of the p-type regions (or the n-type regions) of the parallel pn layer in the depth direction and a method like that in Tamaki, T., et al, “Vertical Charge Imbalance Effect on 600 V-class Trench-filling Superjunction Power MOSFETs”, in which the widths of the n-type regions and the p-type regions of the parallel pn layer are varied in the depth direction.

Further, as another method of forming the SJ structure, a multistage epitaxial method is commonly known in which epitaxial growth of an n-type epitaxial layer is divided into multiple stages (multiple sessions) and for each stage, an ion implantation mask having openings at predetermined locations is formed on the n-type epitaxial layer, the ion implantation mask is used as a mask to ion-implant a p-type impurity, whereby in each n-type epitaxial layer epitaxially grown at each stage, regions that are to form the p-type regions of the parallel pn layer are selectively formed while regions that are to form the n-type regions of the parallel pn layer are left.

As for a conventional silicon carbide semiconductor device having a SJ structure, a device has been proposed that is a vertical semiconductor device having a planar gate structure in which directly beneath a center portion of a gate electrode, a thickness of a gate insulating film is relatively thick and the impurity concentrations of the n-type regions and the p-type regions of the parallel pn layer are set relatively high, whereby on-resistance decreases and directly beneath a p-type base region, the impurity concentrations of the n-type regions and the p-type regions of the parallel pn layer are set relatively low, whereby device breakdown voltage is sustained (for example, refer to Japanese Laid-Open Patent Publication No. 2011-018877).

As for another conventional silicon carbide semiconductor device having a SJ structure, a device has been proposed in which SJ trenches that are embedded with the n-type regions of the parallel pn layer have, in a cross-sectional view, a tapered shape in which the width of the SJ trench becomes narrower in the depth direction of the SJ trench, the p-type regions of the parallel pn layer are formed by multiple sessions of ion implantation to the sidewalls of the SJ trenches, from mutually different oblique angles, and the impurity concentration of the p-type regions is decreased to have a constant gradient in direction to a drain region, whereby the charge balance of the n-type regions and the p-type regions adjacent to one another in the parallel pn layer is kept uniform in the depth direction and a high maximum breakdown voltage is maintained (for example, refer to Japanese Laid-Open Patent Publication No. 2007-019146).

### SUMMARY OF THE INVENTION

According to an embodiment, a silicon carbide semiconductor device includes: a semiconductor substrate containing silicon carbide, the semiconductor substrate having a first main surface and a second main surface that are opposite to each other; a parallel pn layer provided in the semiconductor substrate, the parallel pn layer having therein a plurality of first-conductivity-type regions and a plurality of second-conductivity-type regions disposed adjacent to one another so as to repeatedly alternate with one another in a direction that is parallel to the first main surface of the semiconductor substrate; a device structure provided between the first main surface and the parallel pn layer; a first electrode provided on the first main surface and electrically connected to the device structure; and a second electrode provided on the second main surface of the semiconductor substrate. The parallel pn layer has a standard portion, a first portion and a second portion, the standard portion being located at a standard depth that is a center of the parallel pn layer in a depth direction or having a range of depth, a center of the range of depth being located at the standard depth, the first portion being located closer to the first main surface than is the standard portion, the second portion being located closer to the second main surface than is the standard portion. Between each adjacent two regions that includes one first-conductivity-type region and one second-conductivity-type region of the parallel pn layer that are adjacent to each other: in the standard portion, an amount of a first-conductivity-type charge and an amount of a second-conductivity-type charge meet a standard condition; in the first portion, an amount of the second-conductivity-type charge is greater than an amount of the first-conductivity-type charge, is greater than an amount of the second-conductivity-type charge in the standard portion, and continuously increases with a first gradient in a first direction that is the depth direction from the standard portion toward the first main surface; in the second portion, an amount of the first-conductivity-type charge is greater than the amount of the second-conductivity-type charge, an amount of the second-conductivity-type charge is less than the amount of the second-conductivity-type charge of the standard portion, and continuously decreases with a second gradient in a second direction that is the depth direction from the standard portion toward the second main surface.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to an embodiment.

FIG. 2 is a cross-sectional view depicting an arbitrary n-type region and p-type region that are adjacent to each other in a parallel pn layer depicted in FIG. 1.

FIG. 3 is a distribution diagram depicting charge balance distribution (in a depth direction) of the n-type region and the p-type region adjacent to each another in the parallel pn layer depicted in FIG. 2.

FIG. 4 is a cross-sectional view depicting another example of the arbitrary n-type region and p-type region that are adjacent to each other in the parallel pn layer depicted in FIG. 1.

FIG. 5 is a distribution diagram depicting the charge balance distribution (in the depth direction) of the n-type region and the p-type region adjacent to each another in the parallel pn layer in FIG. 4.

FIG. 6 is a cross-sectional view depicting a state of the silicon carbide semiconductor device according to the embodiment during manufacture.

FIG. 7 is a distribution diagram depicting an example of the charge balance distribution (in the depth direction) of the n-type region and the p-type region adjacent to one another in the parallel pn layer depicted in FIG. 6.

FIG. 8 is a characteristics diagram showing a relationship between breakdown voltage and a width of p-type regions of a parallel pn layer, in an example.

FIG. 9 is a characteristics diagram showing a relationship between breakdown voltage and a width of p-type regions of a parallel pn layer, in a conventional example.

FIG. 10 is a characteristics diagram showing a relationship between conformity rates and the width of the p-type regions of the parallel pn layer, in the example and the conventional example.

### DETAILED DESCRIPTION OF THE INVENTION

First, problems associated with the conventional techniques are discussed. In a method of manufacturing the conventional silicon carbide semiconductor device, even when the trench embedding epitaxial method or the multistage epitaxial method is used to form the parallel pn layer, dimensional deviation of the width of the p-type regions (or the n-type regions) of the parallel pn layer from a design value (suitable value) easily occurs. In the multistage epitaxial method, dimensional deviation due to the precision of the opening of the ion implantation mask easily occurs, and particularly in an instance in which the p-type regions of the parallel pn layer are formed by ion-implanting aluminum (Al), the width of the p-type regions becomes as much as about 1 µm narrower than the design value.

The breakdown voltage decreases as the deviation of the width of the p-type regions (or the n-type regions) of the parallel pn layer from a standard condition increases. In terms of design, a standard condition is a condition of the charge balance of the n-type regions and the p-type regions adjacent to one another in the parallel pn layer obtaining the greatest breakdown voltage and, for example, is a condition that generally maintains the charge balance (equilibrium) between the n-type regions and the p-type regions adjacent to one another in the parallel pn layer, when the widths of the n-type regions and the p-type regions of the parallel pn layer are substantially uniform in the depth direction. A width being substantially uniform means that the width is the same within a range that includes an allowable error due to process variation.

Embodiments of a silicon carbide semiconductor device according to the present invention are described in detail with reference to the accompanying drawings. In the present description and accompanying drawings, layers and regions prefixed with n or p mean that majority carriers are electrons or holes. Additionally, + or - appended to n or p means that the impurity concentration is higher or lower, respectively, than layers and regions without + or -. In the description of the embodiments below and the accompanying drawings, main portions that are identical are given the same reference numerals and are not repeatedly described.

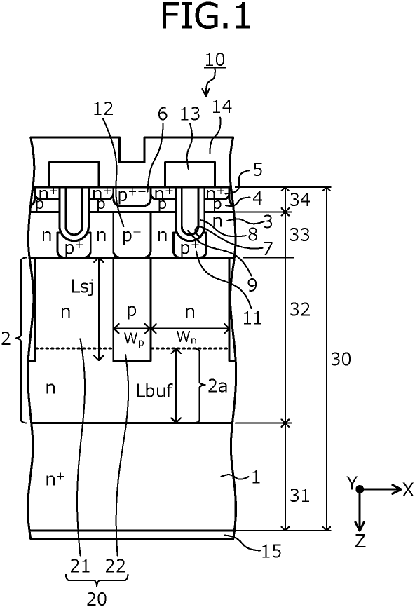

A structure of a silicon carbide semiconductor device according to an embodiment is described taking, as an example, a metal oxide semiconductor field effect transistor (MOSFET) that has an insulated gate with 3-layer structure including a metal, an oxide film, and a semiconductor. FIG. 1 is a cross-sectional view depicting the structure of the silicon carbide semiconductor device according to the embodiment. FIG. 1 depicts a portion of unit cells among multiple unit cells (functional units of the device) each having the same structure and disposed in an active region.

A silicon carbide semiconductor device 10 according to the embodiment depicted in FIG. 1 is a vertical MOSFET that has in the active region in a semiconductor substrate (semiconductor chip) 30 that contains silicon carbide (SiC), a general trench gate structure (device structure) provided at a front surface (first main surface) of the semiconductor substrate 30, the silicon carbide semiconductor device 10 having a SJ structure in which a drift layer (drift region) 2 is constituted by a parallel pn layer 20. The active region is a region through which a main current flows when the MOSFET is in an on-state and is disposed in a center of the semiconductor substrate 30. An edge termination region (not depicted) is a region between the active region and an end of the semiconductor substrate 30, the edge termination region surrounds a periphery of the active region.

The edge termination region has a function of mitigating electric field of the drift layer 2 in the active region, in a front side of the semiconductor substrate 30 and sustaining the breakdown voltage. The breakdown voltage is a voltage limit at which leakage current does not excessively increase, and malfunction and/or destruction of the device do not occur. In the edge termination region, a voltage withstanding structure such as a field limiting ring (FLR), a junction termination extension (JTE) structure, etc. is disposed.

The semiconductor substrate 30 is formed by sequentially stacking, on a front surface of an n⁺-type starting substrate 31 containing silicon carbide, epitaxial layers 32, 33, 34 constituting the drift layer 2, an n-type current spreading region 3, and a p-type base region 4. The semiconductor substrate 30 has, as a front surface, a main surface having the p-type epitaxial layer 34 and has, as a back surface (second main surface), a main surface (back surface of the n⁺-type starting substrate 31) having the n⁺-type starting substrate 31. The n⁺-type starting substrate 31 constitutes an n⁺-type drain region 1. Between the p-type base region 4 and the n⁺-type drain region 1, the drift layer 2 (n-type epitaxial layer (first-conductivity-type epitaxial layer) 32) is in contact with the n⁺-type drain region 1.

In the drift layer 2, at least a surface region (the front side of the semiconductor substrate 30) thereof facing n⁺-type source regions 5 constitutes the parallel pn layer 20. The parallel pn layer 20 is a SJ structure in which n-type regions (first-conductivity-type regions) 21 and p-type regions (second-conductivity-type regions) 22 are disposed adjacent to one another so as to repeatedly alternate with one another in a first direction X parallel to the front surface of the semiconductor substrate 30. In the drift layer 2, a portion thereof that is between the parallel pn layer 20 and the n⁺-type drain region 1 may be an n-type buffer region (n-type region excluded from the SJ structure) 2a. The impurity concentration of the n-type buffer region 2a is at most equal to an impurity concentration of the n-type regions 21 of the parallel pn layer 20.

A thickness Lsj of the parallel pn layer 20 is determined by a thickness of the p-type regions 22 of the parallel pn layer 20. In an instance in which the n-type buffer region 2a is provided, the p-type regions 22 of the parallel pn layer 20 may reach a deeper position closer to the n⁺-type drain region 1 (the back surface of the semiconductor substrate 30) in a depth direction Z than are the n-type regions 21. In this instance, between the p-type regions 22 that are adjacent to one another in the parallel pn layer 20, the n-type buffer region 2a extends a predetermined length from the n⁺-type drain region 1. In the n-type buffer region 2a, portions thereof between the p-type regions 22 that are adjacent to one another function as the parallel pn layer 20.

Respective widths (widths in the first direction X) Wₙ, W_{p of} the n-type regions 21 and the p-type regions 22 of the parallel pn layer 20 are substantially uniform in the depth direction Z. The impurity concentration of the n-type regions 21 of the parallel pn layer 20 is substantially uniform in the depth direction Z. The impurity concentration of the p-type regions 22 of the parallel pn layer 20 varies in the depth direction Z by an impurity concentration distribution that is a same as a charge balance distribution of the n-type regions 21 and the p-type regions 22 adjacent to one another in the parallel pn layer 20. When the impurity concentration of the p-type regions 22 is increased with respect to the n-type regions 21, an effect of the embodiment may be further obtained. The charge balance distribution of the n-type regions 21 and the p-type regions 22 adjacent to one another in the parallel pn layer 2 is described hereinafter.

The charge balance is an index that indicates a degree of equilibrium between an amount of charge expressed by a product obtained by multiplying carrier concentration (impurity concentration) of the n-type regions 21 of the parallel pn layer 20 and a width Wₙ of the n-type regions 21, and an amount of charge expressed by a product obtained by multiplying carrier concentration of the p-type regions 22 and a width Wₚ of the p-type regions 22. The width and the impurity concentration being substantially uniform means a same width and a same impurity concentration within a range that includes an allowable error due to process variation. The carrier concentrations and the widths Wₙ, Wₚ of the n-type regions 21 and the p-type regions 22 of the parallel pn layer 20 are suitably set and may be substantially the same or may be different from each other.

While not depicted, when viewed from the front side of the semiconductor substrate 30, the parallel pn layer 20 may have a layout in which, for example, the n-type regions 21 and the p-type regions 22 extend in a striped pattern, in a second direction Y that is parallel to the front surface of the semiconductor substrate 30 and orthogonal to the first direction X. Alternatively, when viewed from the front side of the semiconductor substrate 30, the parallel pn layer 20 may have a layout in which, for example, the p-type regions 22 are disposed in a matrix-like pattern (in dot shapes) and the n-type regions 21 are disposed as a lattice-like pattern surrounding peripheries of the p-type regions 22.

The trench gate structure is configured by the p-type base region 4, the n⁺-type source regions 5, p⁺⁺-type contact regions 6, gate trenches 7, gate insulating films 8, and gate electrodes 9. The p-type base region 4 is provided between the front surface of the semiconductor substrate 30 and the drift layer 2. The p-type base region 4 is a portion of the p-type epitaxial layer 34, excluding the n⁺-type source regions 5 and the p⁺⁺-type contact regions 6. The n⁺-type source regions 5 and the p⁺⁺-type contact regions 6 are each selectively provided between the front surface of the semiconductor substrate 30 and the p-type base region 4.

The n⁺-type source regions 5 and the p⁺⁺-type contact regions 6 are in contact with the p-type base region 4 and are exposed at the front surface of the semiconductor substrate 30. Being exposed at the front surface of the semiconductor substrate 30 means that the n⁺-type source regions 5 and the p⁺⁺-type contact regions 6 are in contact with a later-described source electrode (first electrode) 14 at the front surface of the semiconductor substrate 30. The p⁺⁺-type contact regions 6 may be omitted. In this instance, instead of the p⁺⁺-type contact regions 6, the p-type base region 4 is exposed at the front surface of the semiconductor substrate 30.

Between the p-type base region 4 and the parallel pn layer 20 (the drift layer 2), the n-type current spreading region 3 and p⁺-type regions 11, 12 are each selectively provided. The n-type current spreading region 3 is a portion of the n-type epitaxial layer 33, excluding the p⁺-type regions 11, 12. The p⁺-type regions 11, 12 are diffused regions formed by ion implantation in the n-type epitaxial layer 33. The n-type current spreading region 3 and the p⁺-type regions 11, 12 reach deeper positions closer to the n⁺-type drain region 1 than are bottoms of the gate trenches 7.

The n-type current spreading region 3 is a so-called current spreading layer (CSL) that reduces carrier spreading resistance. Between the gate trenches 7 that are adjacent to one another, the n-type current spreading region 3 is in contact with the p⁺-type regions 11, 12, the p-type base region 4, and the n-type regions 21 of the parallel pn layer 20; the n-type current spreading region 3 extends in the first direction X and forms the sidewalls of the gate trenches 7. An impurity concentration of the n-type current spreading region 3 is at least equal to the impurity concentration of the n-type regions 21 of the parallel pn layer 20.

The p⁺-type regions 11, 12 are electrically connected to the source electrode 14, are depleted during an off-state of the MOSFET, and have a function of mitigating electric field close to the bottoms of the gate trenches 7. The p⁺-type regions 11 are disposed to be apart from the p-type base region 4 and face the bottoms of the gate trenches 7 in the depth direction Z. The p⁺-type regions 11 are connected to the p⁺-type regions 12 at a portion not depicted in the figures. The p⁺-type regions 11 face the n-type current spreading region 3 in the depth direction Z. The p⁺-type regions 11 may be in contact with the n-type current spreading region 3 in the depth direction Z.

Between the gate trenches 7 that are adjacent to one another, the p⁺-type regions 12 are provided apart from the p⁺-type regions 11 and the gate trenches 7 and in contact with the p-type base region 4. The p⁺-type regions 12 face the p-type regions 22, respectively, in the depth direction Z. The p⁺-type regions 12 may be in contact with the p-type regions 22 that the p⁺-type regions 12 respectively face in the depth direction Z. The gate trenches 7 penetrate through the n⁺-type source regions 5 and the p-type base region 4 in the depth direction Z and reach the n-type current spreading region 3. The gate trenches 7 extend in a striped pattern in a direction (herein, the second direction Y) parallel to the front surface of the semiconductor substrate 30.

The gate electrodes 9 are provided in the gate trenches 7 via the gate insulating films 8, respectively. MOS gates of trench gate structure are configured by the gate trenches 7, the gate insulating films 8, and the gate electrodes 9. An interlayer insulating film 13 is provided in an entire area of the front surface of the semiconductor substrate 30 and covers the gate electrodes 9. The source electrode 14 is electrically connected to the n⁺-type source regions 5 and the p⁺⁺-type contact regions 6, in contact holes of the interlayer insulating film 13. A drain electrode (second electrode) 15 is provided in an entire area of the back surface of the semiconductor substrate 30.

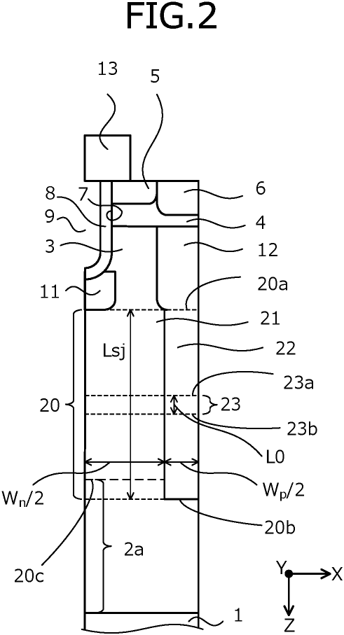

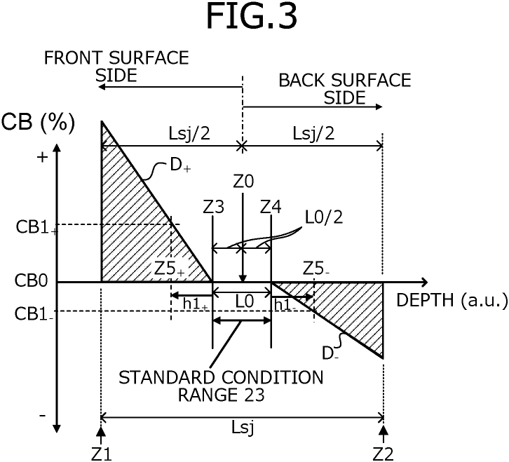

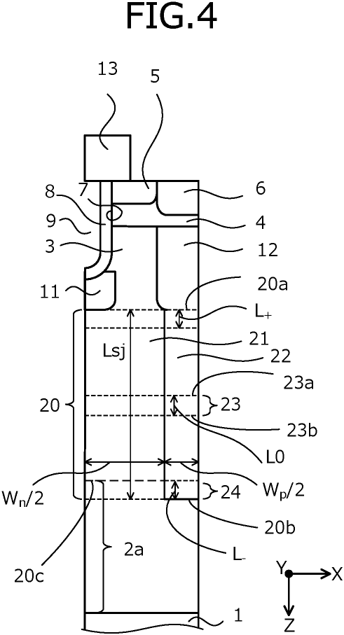

Charge balance distribution of the n-type regions 21 and the p-type regions 22 adjacent to one another in the parallel pn layer 20 is described. FIG. 2 is a cross-sectional view depicting an arbitrary n-type region and p-type region that are adjacent to each other in the parallel pn layer depicted in FIG. 1. FIG. 2 depicts a portion (portion corresponding to half of the n-type region 21 and the p-type region 22 in the width Wₙ, Wₚ directions thereof) between centers of the adjacent n-type region 21 and the p-type region 22 of the parallel pn layer 20, in the width Wₙ, Wₚ directions thereof along the first direction X (similarly in later-described FIG. 4). FIG. 3 is a distribution diagram depicting the charge balance distribution (in the depth direction) of the n-type region and the p-type region adjacent to each another in the parallel pn layer depicted in FIG. 2.

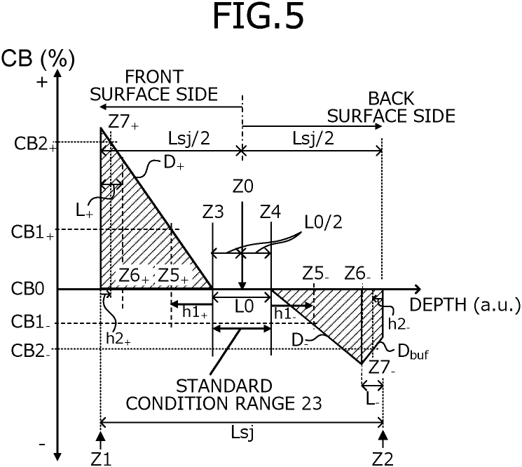

The distribution of charge balance CB (charge balance) depicted in FIG. 3 is applicable to all the n-type regions 21 and the p-type regions 22 that are adjacent to one another in the parallel pn layer 20. In FIG. 3, a horizontal axis indicates depth [arbitrary unit (a.u.] from the front surface of the semiconductor substrate 30. In FIG. 3, a vertical axis indicates charge balance CB[%] of the n-type region 21 and the p-type region 22 adjacent to each other in the parallel pn layer 20, a p-rich range being indicated on a positive (+) side of the graph and an n-rich range being indicated on a negative (-) side of the graphs. The charge balance CB and conditions of the horizontal axis and the vertical axis in FIG. 3 similarly apply to later-described FIG. 5.

The charge balance CB of the n-type region 21 and the p-type region 22 that are adjacent to each other in the parallel pn layer 20 is p-rich (positive value in FIG. 3) in a portion (the front side of the semiconductor substrate 30) that is closer to the n⁺-type source region 5 than is a depth position (hereinafter, center position) Z0 that corresponds to ½ of the thickness Lsj of the parallel pn layer 20 (=Lsj/2) and is n-rich (negative value in FIG. 3) in a portion (back side of the semiconductor substrate 30) that is closer to the n⁺-type drain region 1 than is the center position Z0. The charge balance CB of the n-type region 21 and the p-type region 22 that are adjacent to each other in the parallel pn layer 20 is a standard condition at the center position Z0.

The amount of charge of the p-type region 22 of the parallel pn layer 20, in the portion that is closer to the n⁺-type source region 5 than is the interface at the center position Z0, is greater than the amount of charge of the p-type region 22 of the standard condition; and the amount of charge of the p-type region 22 in the portion that is closer to the n⁺-type drain region 1 than is the interface at the center position Z0, is less than the amount of charge of the p-type region 22 of the standard condition. P-rich means that the amount of charge of the p-type region 22 is greater than the amount of charge of the n-type region 21, at a location of the p-type region 22 adjacent to the n-type region 21. N-rich means that the amount of charge of the n-type region 21 is greater than the amount of charge of the p-type region 22, at a location of the n-type region 21 adjacent to the p-type region 22.

A standard condition, in terms of design, is a condition of the charge balance of the n-type region 21 and the p-type region 22 that are adjacent to each other in the parallel pn layer 20, said condition obtaining the greatest breakdown voltage and corresponding to the charge balance CB0 in FIG. 3. In particular, a standard condition, for example, is a condition (the charge balance CB calculated by later-described equation (1) is 0%) that generally keeps the charge balance (equilibrium) of the n-type region 21 and the p-type region 22 that are adjacent to each other in the parallel pn layer 20, and may be an n-rich condition, whereby the charge balance CB calculated by equation (1) is less than 0% to about -15%.

The parallel pn layer 20 may be a standard condition in a predetermined thickness range (hereinafter, standard condition range) 23 that includes the center position Z0 in the depth direction Z. The standard condition range 23 has a predetermined width L0 that is thinner than the thickness Lsj of the parallel pn layer 20 and symmetrical in the depth direction Z with respect to the center position Z0 as a reference. The standard condition range 23 has an end 23a facing the n⁺-type source regions 5 and an end 23b facing the n⁺-type drain region 1, and is such that a distance from the center position Z0 to the end 23a and a distance from the center position Z0 to the end 23b are substantially the same (½ of the width L0). Substantially the same distance means the same distance in a range that includes an allowable error due to process variation.

The charge balance CB of the n-type region 21 and the p-type region 22 that are adjacent to each other in the parallel pn layer 20 is adjusted by varying the impurity concentration of the p-type regions 22 in the depth direction Z by a predetermined impurity concentration distribution. As described above, the respective widths Wₙ, Wₚ of the n-type region 21 and the p-type region 22 of the parallel pn layer 20 are substantially uniform in the depth direction Z and the impurity concentration of the n-type region 21 is substantially uniform in the depth direction Z, whereby an impurity concentration distribution of the p-type region 22 of the parallel pn layer 20 is a distribution of the charge balance CB of the n-type region 21 and the p-type region 22 that are adjacent to each other in the parallel pn layer 20.

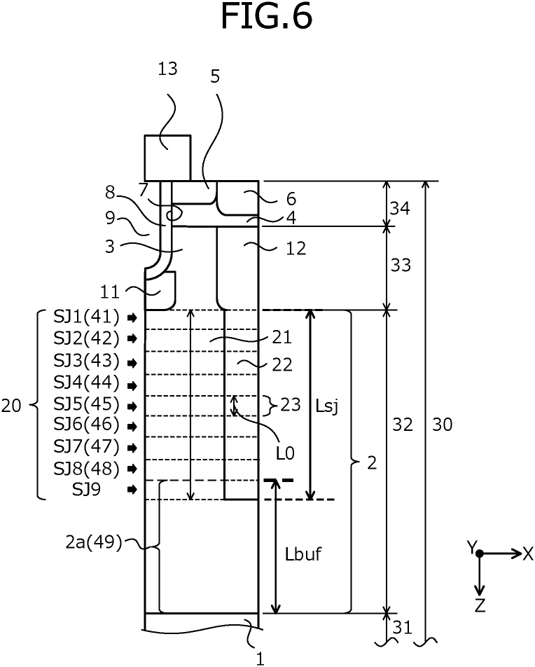

For example, as described hereinafter, the parallel pn layer 20 is formed by dividing the epitaxial growth of the n-type epitaxial layer 32 constituting the drift layer 2 into multiple stages (multiple sessions) and for each stage of epitaxial growth, in the n-type epitaxial layer (each of the n-type epitaxial layers (corresponds to first-conductivity-type epitaxial layer) 49, 48, 47, 46, 45, 44, 43, 42, 41 depicted in later-described FIG. 6) of each of the stages, a p-type impurity (second-conductivity-type impurity) is ion-implanted so that, in the depth direction Z, a predetermined impurity concentration distribution of the p-type region 22 is formed, whereby portions (second-conductivity-type diffused regions) that are to become the p-type region 22 are selectively formed respectively having different impurity concentrations and portions of the n-type epitaxial layer 32 free of the ion implantation and left as an n-type form the n-type region 21.

At this time, of the epitaxial layers, which have substantially the same thickness and are epitaxially grown in multiple stages as the n-type epitaxial layer 32, at least the epitaxial layer of a middle stage (one stage when the total number of stages is odd, two stages when the total number of stages is even) may be set in the standard condition range 23. The width L0 of the standard condition range 23 may be increased by setting the epitaxial layers of an equal number of stages before and after the middle stage to the standard condition range 23. Substantially the same thickness means the same thickness within a range that includes an allowable error due to process variation.

In particular, the charge balance CB[%] of the n-type region 21 and the p-type region 22 that are adjacent to each other in the parallel pn layer 20 is calculated by equation (1) below, based on an amount of charge Qₙ of the n-type regions 21 and an amount of charge Qₚ of the p-type regions 22 of the parallel pn layer 20. In equation (1), Nₐ and Wₚ are, respectively, the carrier concentration (hole concentration) and the width in the first direction X of the p-type region 22 of the parallel pn layer 20. N_{d} and Wₙ are, respectively, the carrier concentration (electron concentration) and the width in the first direction X of the parallel pn layer 20.

$$\text{CB} = \frac{{Q}_{p} - {Q}_{n}}{{Q}_{n}} \times 100 \qquad \text{(1)}$$

$$\begin{matrix}( \text{Where} , {Q}_{p} = {N}_{a} \times {W}_{p} \\ {Q}_{n} = {N}_{d} \times {W}_{n} )\end{matrix}$$

When calculated based on equation (1), the charge balance CB[%] of the n-type region 21 and the p-type region 22 that are adjacent to each other in the parallel pn layer 20, from the center position Z0 (in an instance of having the standard condition range 23, the depth position Z3 of the end 23a of the standard condition range 23, facing the n⁺-type source region 5), is a positive value in the portion (p-rich range) of the semiconductor substrate 30, closer to the n⁺-type source region 5 than is the center position Z0 and in a direction to the n⁺-type source region 5, increases by a predetermined first gradient D+ (the amount of charge of the p-type region 22 is greater than amount of charge of the p-type region 22 of the standard condition).

When the charge balance CB[%] of the n-type region 21 and the p-type region 22 that are adjacent to each other in the parallel pn layer 20 is calculated based on equation (1), from the center position Z0 (in an instance of having the standard condition range 23, a depth position Z4 of the end 23b of the standard condition range 23, the end 23b facing the n⁺-type drain region 1), the charge balance CB[%] is a negative value in the portion (n-rich range) of the semiconductor substrate 30, closer to the n⁺-type drain region 1 than is the center position Z0 and in a direction to the n⁺-type drain region 1, decreases by a predetermined second gradient D- (the amount of charge of the p-type region 22 is less than the amount of charge of the p-type region 22 of the standard condition).

The charge balance CB of the n-type region 21 and the p-type region 22 that are adjacent to each other in the parallel pn layer 20 may have an upper limit (a positive value at a depth position Z1 of an end 20a of the parallel pn layer 20, the end 20a facing the n⁺-type source region 5) set as +160% in the front side (p-rich range) of the semiconductor substrate 30, closer to the n⁺-type source region 5 than is the center position Z0, and a lower limit (a negative value at a depth position Z2 of an end 20b of the parallel pn layer 20, the end 20b facing the n⁺-type drain region 1) set as -30% in the back side (n-rich range) of the semiconductor substrate 30, closer to the n⁺-type drain region 1 than is the center position Z0. As for the charge balance CB of the n-type region 21 and the p-type region 22 that are adjacent to each other in the parallel pn layer 20, an absolute value of the first gradient D₊ of the p-rich range may be greater than an absolute value of the second gradient D₋ of the n-rich range (|D₊|>|D₋|).

When the charge balance CB (positive value) of the n-type region 21 and the p-type region 22 that are adjacent to each other in the parallel pn layer 20 increases by the first gradient D₊, the charge balance CB may increase linearly in a direction from the center position Z0 to the n⁺-type source regions 5 (FIG. 3) or may increase stepwise (not depicted). When the charge balance CB (negative value) of the n-type region 21 and the p-type region 22 that are adjacent to each other in the parallel pn layer 20 decreases by the second gradient D₋, the charge balance CB may decrease linearly in a direction from the center position Z0 to the n⁺-type drain region 1 (FIG. 3) or may decrease stepwise (not depicted).

Further, in the charge balance CB of the n-type region 21 and the p-type region 22 that are adjacent to each other in the parallel pn layer 20, for a first distance h1₊ from the center position Z0 (in an instance of having the standard condition range 23, the depth position Z3), a first charge balance CB1₊ of the p-rich range at a predetermined depth position Z5₊ closer to the n⁺-type source region 5 than is the center position Z0, and for a second distance h1₋ that is from the center position Z0 (in an instance of having the standard condition range 23, the depth position Z4) and substantially equal to the first distance h1₊, a second charge balance CB1₋ of the n-rich range at a predetermined depth position Z5₋ closer to the n⁺-type drain region 1 than is the center position Z0, may satisfy expression (2) below.

$$5 \leq \left|\frac{{\text{CB1}}_{+}}{{\text{CB1}}_{-}}\right| \leq 6 \qquad \text{(2)}$$

Another example of the silicon carbide semiconductor device 10 according to the embodiment is described. FIG. 4 is a cross-sectional view depicting another example of the arbitrary n-type region and p-type region that are adjacent to each other in the parallel pn layer depicted in FIG. 1. FIG. 5 is a distribution diagram depicting the charge balance distribution (in the depth direction) of the n-type region and the p-type region adjacent to each another in the parallel pn layer in FIG. 4. FIG. 5 depicts the charge balance distribution (in the depth direction Z) of the n-type region 21 and the p-type region 22 that are adjacent to each other in the parallel pn layer 20, in an instance in which the impurity concentration of the n-type buffer region 2a is less than the impurity concentration of the n-type regions 21 of the parallel pn layer 20.

In an instance in which the impurity concentration of the n-type buffer region 2a and the impurity concentration of the n-type regions 21 of the parallel pn layer 20 are substantially the same, the charge balance distribution in the depth direction Z is the charge balance distribution of the n-type region 21 and the p-type region 22 that are adjacent to each other in the parallel pn layer 20 depicted in FIG. 3 described above. Substantially the same impurity concentration means the same impurity concentration within a range that includes an allowable error due to process variation. In an instance in which the impurity concentration of the n-type buffer region 2a is less than the impurity concentration of the n-type regions 21 of the parallel pn layer 20, the charge balance distribution (in the depth direction) of the n-type region 21 and the p-type region 22 that are adjacent to each another in the parallel pn layer 20 satisfies the following two differences in addition to the conditions described above.

The first difference is that the charge balance CB of the n-type region 21 and the p-type region 22 that are adjacent to each other in the parallel pn layer 20 is the most n-rich at a depth position Z6₋ of an interface 20c between the n-type buffer region 2a and the n-type region 21 of the parallel pn layer 20. In other words, when calculated based on equation (1), the charge balance CB[%] of the n-type region 21 and the p-type region 22 that are adjacent to each other in the parallel pn layer 20 decreases from the center position Z0 (in an instance of having the standard condition range 23, the depth position Z4) by the predetermined second gradient D₋ in a direction to the n⁺-type drain region 1, and has a smallest value at the depth position Z6₋ of the interface 20c between the n-type buffer region 2a and the n-type region 21 of the parallel pn layer 20.

The charge balance CB of the n-type region 21 and the p-type region 22 that are adjacent to each other in the parallel pn layer 20 may be constant in the depth direction Z, in a portion 24 where the n-type buffer region 2a and the p-type region 22 of the parallel pn layer 20 are adjacent to each other in the first direction X (not depicted), or may increase in a direction to the n⁺-type drain region 1 by a predetermined third gradient D_{buf} (FIG. 5). The portion 24 where the n-type buffer region 2a and the p-type region 22 of the parallel pn layer 20 are adjacent to each other in the first direction X is an n-rich range from the depth position Z6₋ of the interface 20c between the n-type buffer region 2a and the n-type region 21 of the parallel pn layer 20, to the depth position Z2 of the end 20b (the interface between the n-type buffer region 2a and the p-type region 22 of the parallel pn layer 20) of the parallel pn layer 20, the end 20b facing the n⁺-type drain region 1.

The second difference is that the charge balance CB of the n-type region 21 and the p-type region 22 that are adjacent to each other in the parallel pn layer 20 may satisfy expression (3) below. In particular, in the n-rich range in the portion 24 where the n-type buffer region 2a and the p-type region 22 of the parallel pn layer 20 are adjacent to each other in the first direction X, a charge balance distribution of the third gradient D_{buf} forming a fourth charge balance CB2₋ is formed at a predetermined depth position Z7₋. In the p-rich range, from the depth position Z1 of the end 20a of the parallel pn layer 20 (the end 20a facing the n⁺-type source region 5) to the depth position Z6₊ in a direction to the n⁺-type drain region 1 (equivalent to a thickness L₊ that is substantially equal to a thickness L₋ of the portion 24), a charge balance distribution of the first gradient D₊ forming a third charge balance CB2₊ is formed at a predetermined depth position Z7₊.

In the portion 24 where the n-type buffer region 2a and the p-type region 22 of the parallel pn layer 20 are adjacent to each other in the first direction X, the fourth charge balance CB2₋ at the depth position Z7₋ that is a predetermined fourth distance h2₋ from the depth position Z2 of the end 20b of the parallel pn layer 20 (the end 20b facing the n⁺-type drain region 1) in a direction to the n⁺-type source region 5 and the third charge balance CB2₊ at the depth position Z7₊ that is a third distance h2₊ from the depth position Z1 of the end 20a of the parallel pn layer 20 (the end 20a facing the n⁺-type source region 5 and the third distance h2₊ being substantially equal to the fourth distance h2₋) satisfy expression (3). The charge balance distributions forming the third and first charge balances CB2₊, CB1₊ at the predetermined depth positions Z7₊, Z5₊, respectively, are continuous with each other at the interface at the depth position Z6₊, by the first gradient D₊.

$$5 \leq \left|\frac{{\text{CB2}}_{+}}{{\text{CB2}}_{-}}\right| \leq 20 \qquad \text{(3)}$$

In p-rich range, from the center position Z0 (in an instance of having the standard condition range 23, the depth position Z3) to the depth position Z6₊ that is the third distance h2₊ from the depth position Z1 of the end 20a of the parallel pn layer 20 (the end 20a facing the n⁺-type source region 5), in a direction to the n⁺-type drain region 1, similar to FIG. 3, the charge balance distribution of the first gradient D₊ forming the first charge balance CB1₊ that satisfies expression (2) is formed at the predetermined depth position Z5₊. In the n-rich range, from the center position Z0 (in an instance of having the standard condition range 23, the depth position Z4) to the depth position Z6₋ of the interface 20c between the n-type buffer region 2a and the n-type region 21 of the parallel pn layer 20, similar to FIG. 3, the charge balance distribution of the second gradient D₋ forming the second charge balance CB1₋ that satisfies expression (2) is formed at the predetermined depth position Z5₋.

A method of manufacturing the silicon carbide semiconductor device 10 according to the embodiment is described. FIG. 6 is a cross-sectional view depicting a state of the silicon carbide semiconductor device according to the embodiment during manufacture. First, on the front surface of the n⁺-type starting substrate (semiconductor wafer) 31 constituting the n⁺-type drain region 1, the drift layer 2 that includes the parallel pn layer 20 is formed. At this time, the multistage epitaxial method is used and for each of the multiple stages into which the epitaxial growth of the n-type epitaxial layer 32 constituting the drift layer 2 is divided, a p-type impurity such as aluminum (Al) is ion-implanted in the n-type epitaxial layer 32, whereby portions constituting the p-type regions 22 of the parallel pn layer 20 are selectively provided.

In the n-type epitaxial layer 32, portions thereof between the p-type regions 22 that are adjacent to one another, free of ion implantation, and left as the n-type constitute the n-type regions 21 of the parallel pn layer 20. FIG. 6 depicts an instance in which the n-type epitaxial layer 32 constituting the drift layer 2 is formed by, for example, 9 stages of epitaxial growth and respective n-type epitaxial layers of these 9 stages are given reference numerals 41, 42, 43, 44, 45, 46, 47, 48, and 49 sequentially from an uppermost surface (surface closest to the n⁺-type source region 5). In the n-type epitaxial layer 32, an entire area of a portion thereof between the parallel pn layer 20 and the n⁺-type starting substrate 31 is free of ion implantation and left as the n-type buffer region 2a. Hereinafter, an instance in which the n-type buffer region 2a is provided is described as an example.

An n-type epitaxial layer 49 that is a lowermost layer constituting the n-type epitaxial layer 32 is formed having the impurity concentration and a thickness Lbuf of the n-type buffer region 2a. A p-type impurity such as aluminum is ion-implanted in surface regions of the n-type epitaxial layer 49, thereby, selectively forming portions that constitute the p-type regions 22. Of the n-type epitaxial layer 49, the portions constituting the p-type regions 22 and portions that are free of the ion implantation and left as the n-type between the p-type regions 22 in the surface regions form a portion SJ9 that is the lowest layer configuring the parallel pn layer 20. Of the n-type epitaxial layer 49, a portion excluding the p-type regions 22 constitutes the n-type buffer region 2a, and between the p-type regions 22 that are adjacent to one another of the portion SJ9 (lowermost layer), portions of the n-type buffer region 2a reach the surface of the n-type epitaxial layer 49.

On the n-type epitaxial layer 49, the n-type epitaxial layers 48 to 41 of the remaining eight stages and constituting the n-type epitaxial layer 32 are epitaxially grown having the impurity concentration of the n-type regions 21 of the parallel pn layer 20. A sum of the thicknesses of the portion SJ9 and the n-type epitaxial layers 48 to 41 of the eight stages is the thickness Lsj of the parallel pn layer 20. A p-type impurity such as aluminum is ion-implanted in the n-type epitaxial layers 48 to 41 under respectively different conditions so that a predetermined impurity concentration distribution of the p-type regions 22 is formed in the depth direction Z spanning the n-type epitaxial layers 49 to 41 connected in the depth direction Z, thereby selectively forming the portions that constitute the p-type regions 22.

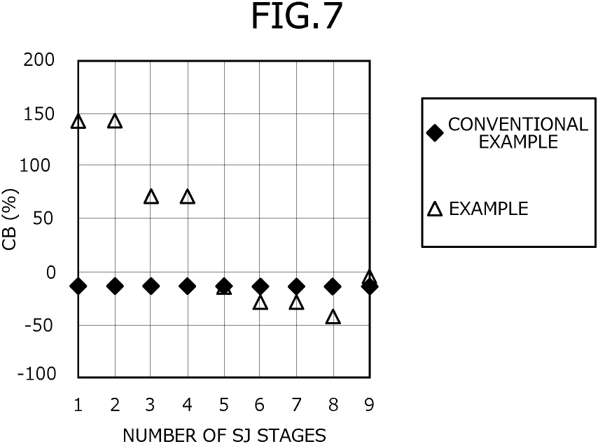

In the n-type epitaxial layers 48 to 41, portions thereof free of the ion implantation and left as the n-type between the p-type regions 22 that are adjacent to one another constitute the n-type regions 21 of the parallel pn layer 20. As a result, portions SJ8, SJ7, SJ6, SJ5, SJ4, SJ3, SJ2, SJ1 configuring the parallel pn layer 20 are formed in the n-type epitaxial layers 48 to 41 of the eight stages, respectively. The impurity concentration of the p-type regions 22 of the portions SJ9 to SJ1 is adjusted so that the charge balance CB of the n-type region 21 and the p-type region 22 that are adjacent to each other in the parallel pn layer 20 satisfies the conditions described above (refer to FIG. 3 and expression (2) or FIG. 5 and expression (3), etc.). FIG. 7 is a distribution diagram depicting an example of the charge balance distribution (in the depth direction) of the n-type region and the p-type region adjacent to one another in the parallel pn layer depicted in FIG. 6.

The impurity concentration of the n-type buffer region 2a is less the impurity concentration of the n-type regions 21 of the parallel pn layer 20 (refer to FIG. 5), and results of simulation of the charge balance CB of the n-type region 21 and the p-type region 22 that are adjacent to each other in the parallel pn layer 20 in an instance in which the portion SJ5 of a middle stage is set as the standard condition range 23 are shown in FIG. 7 (hereinafter, “example”). In FIG. 7, for comparison, charge balance distribution in the depth direction for an n-type region and a p-type region adjacent to each another in a parallel pn layer of a conventional example is shown. The conventional example differs from the example in that the impurity concentration of the p-type region of the parallel pn layer is substantially uniform in the depth direction, the charge balance distribution in the depth direction for the n-type region and the p-type region adjacent to each another in the parallel pn layer is free of a gradient, and all the portions SJ are of the standard condition (condition for the charge balance CB0 depicted in FIG. 3).

In the example, the portions SJ9 to SJ1 are formed having a thickness of 0.65 µm and the thickness Lsj of the parallel pn layer 20 is set as 5.85 µm (=0.65 µm×9). The impurity concentrations of the n-type region 21 and the p-type region 22 of the parallel pn layer 20 of the standard condition are 3×10¹⁶/cm³ and 6×10¹⁶/cm³, respectively. In other words, the impurity concentration of the n-type region 21 of the parallel pn layer 20 is 3×10¹⁶/cm³ and uniform in the depth direction Z. The impurity concentration of the p-type region 22 of the portion SJ5 of the middle stage, set as the standard condition range 23 is 6×10¹⁶/cm³. The thickness Lbuf and the impurity concentration the n-type buffer region 2a are set as 4.4 µm and 1.8×10¹⁶/cm³, respectively.

A breakdown voltage of the example is set as 1200 V. In this instance, as depicted in FIG. 7, as for the charge balance CB of the n-type region 21 and the p-type region 22 that are adjacent to each other in the parallel pn layer 20, the impurity concentration of the p-type regions 22 of the portions SJ9 to SJ1 may be adjusted, for example, to be: p-rich of about +150% in the portions SJ1, SJ2 that are upper layers and about +70% in the portions SJ3, SJ4 therebeneath, the standard condition in the portion SJ5 of the middle stage, and n-rich of about -30% in the portions SJ6, SJ7 therebeneath, about -50% in the portion SJ8 therebeneath, and about -5% in the portion SJ9 therebeneath. In FIG. 7, on a horizontal axis, “1” to “9” indicating the number of SJ stages correspond to the portions SJ1 to SJ9, respectively.

The respective widths Wₙ, W_{p of} the n-type region 21 and the p-type region 22 of the parallel pn layer 20 are uniform in the depth direction Z, and the impurity concentration of the n-type region 21 of the parallel pn layer 20 is uniform in the depth direction Z. Thus, the impurity concentration of the p-type region 22 of the portions SJ9 to SJ1 is adjusted, whereby the charge balance CB of the n-type region 21 and the p-type region 22 that are adjacent to each other in the parallel pn layer 20 may be p-rich closer to the n⁺-type source region 5 than is a portion (the portion SJ5) of the standard condition, may increase by the first gradient D+ in a direction to the n⁺-type source region 5, and may be n-rich closer to the n⁺-type drain region 1 than is the portion SJ5, and may decrease by the second gradient D₋ in a direction to the n⁺-type drain region 1 (refer to FIGS. 3 and 5).

Next, on the n-type epitaxial layer 32 (on the portion SJ1), the n-type epitaxial layer 33 that constitutes the n-type current spreading region 3 is epitaxially grown. Next, the p⁺-type regions 11, 12 are selectively formed by ion implantation in the n-type epitaxial layer 33. A portion of the n-type epitaxial layer 33 free of the ion implantation and left as the n-type constitutes the n-type current spreading region 3. The n-type current spreading region 3 may be formed by epitaxially growing the n-type epitaxial layer 33 to have an impurity concentration that is lower than the impurity concentration of the n-type current spreading region 3 and then, performing ion implantation in the n-type epitaxial layer 33.

Next, on the n-type epitaxial layer 33, the p-type epitaxial layer 34 constituting the p-type base region 4 is epitaxially grown. As a result, the semiconductor substrate (semiconductor wafer) 30 that has the parallel pn layer 20 in the epitaxial layer 32 and in which the epitaxial layers 32 to 34 are sequentially stacked on the n⁺-type starting substrate 31 is fabricated. Next, the n⁺-type source regions 5 and the p⁺⁺-type contact regions 6 are selectively formed in surface regions of the p-type epitaxial layer 34 by ion implantation. A portion of the p-type epitaxial layer 34 excluding the n⁺-type source regions 5 and the p⁺⁺-type contact regions 6 constitutes the p-type base region 4.

Next, a heat treatment (hereinafter, activation annealing) for activating the impurities ion-implanted in the epitaxial layers 32 to 34 is performed. Next, the gate trenches 7 that penetrate the n⁺-type source regions 5 and the p-type base region 4 from the front surface of the semiconductor substrate 30 and face the p⁺-type regions 11 in the n-type current spreading region 3 are formed. Next, by a general method, the gate insulating films 8, the gate electrodes 9, the interlayer insulating film 13, the source electrode 14, and the drain electrode 15 are formed. Thereafter, the semiconductor wafer (the semiconductor substrate 30) is diced (cut) into individual chips, whereby the silicon carbide semiconductor device 10 depicted in FIGS. 1 to 3 is completed.

In the method of manufacturing the silicon carbide semiconductor device 10 according to the embodiment described above, the parallel pn layer 20 may be formed using the trench embedding epitaxial method instead of the multistage epitaxial method. In an instance in which the trench embedding epitaxial method is used, the trenches (SJ trenches) are formed in the n-type epitaxial layer (first-conductivity-type epitaxial layer) 32, portions of the n-type epitaxial layer 32 to constitute the n-type regions 21 are left, and the SJ trenches are embedded with a p-type epitaxial layer (second-conductivity-type epitaxial layer) that constitutes the p-type regions 22, whereby the parallel pn layer 20 is formed.

The p-type regions 22 embedded in the SJ trenches suffice to have a predetermined impurity concentration distribution by suitably changing the impurity concentration during the epitaxial growth of the p-type epitaxial layer that constitutes the p-type regions 22. In an instance in which the impurity concentration of the n-type buffer region 2a is less than the impurity concentration of the n-type regions 21 of the parallel pn layer 20, the n-type epitaxial layer 32 is formed having a two-layer structure including a portion (first semiconductor layer) constituting the n-type buffer region 2a and a portion (second semiconductor layer) constituting the n-type regions 21 of the parallel pn layer 20, and the SJ trenches that terminate in the portion constituting the n-type buffer region 2a suffice to be formed.

As described above, according to the embodiment, a depth position that corresponds to ½ of the thickness of the parallel pn layer is set as a center position, this center position or a depth range of a predetermined width that includes the center position is set as a standard condition, and the charge balance of the n-type regions and the p-type regions adjacent to one another in the parallel pn layer is p-rich in a portion that is closer to the n⁺-type source regions than is the portion of the standard condition, increases by the first gradient in a direction to the n⁺-type source regions, is n-rich in a portion closer to the n⁺-type drain region than is the portion of the standard condition, and decreases by the second gradient in a direction to the n⁺-type drain region. As a result, decreases in the breakdown voltage with respect to variation of the width of the p-type regions of the parallel pn layer may be suppressed, and process margins for dimensional deviation of the width of the p-type regions of the parallel pn layer may be widened.

Further, according to the embodiment, charge balance of the n-type regions and the p-type regions adjacent to one another in the parallel pn layer is implemented by adjusting the impurity concentration distribution in the depth direction for the p-type regions of the parallel pn layer. Thus, when the parallel pn layer is formed using the multistage epitaxial method, ion implantation conditions for forming the p-type regions are suitably changed, or when the parallel pn layer is formed using the trench embedding epitaxial method, growth conditions are suitably changed during the epitaxial growth of the p-type epitaxial layer that is embedded in the SJ trenches, so that the p-type regions of the parallel pn layer have a predetermined impurity concentration distribution in the depth direction. Therefore, according to the embodiment, application to an existing manufacturing line is facilitated.

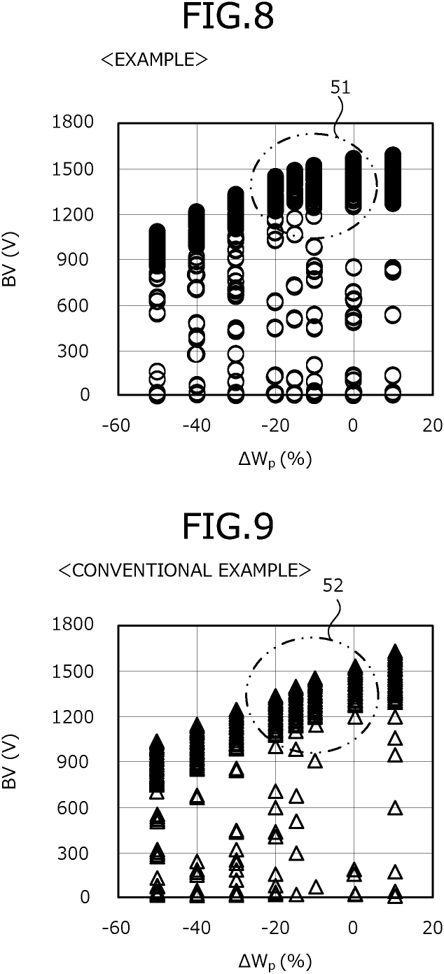

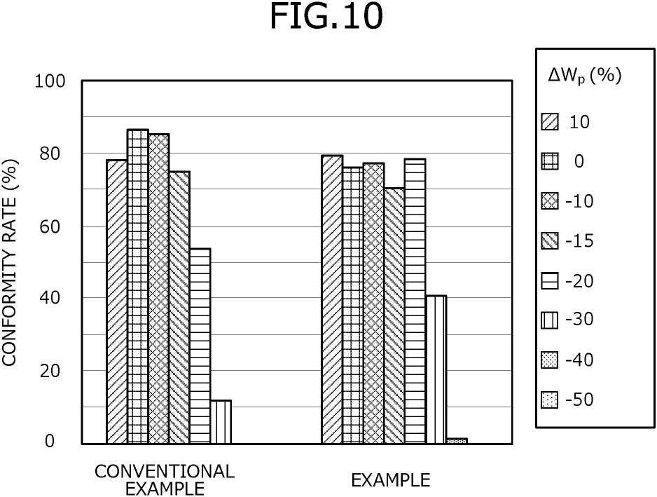

A process margin for the width Wₚ of the p-type regions 22 of the parallel pn layer 20 the silicon carbide semiconductor device 10 according to the embodiment was verified. FIG. 8 is a characteristics diagram showing a relationship between the breakdown voltage and the width of the p-type regions of the parallel pn layer, in the example. FIG. 9 is a characteristics diagram showing a relationship between the breakdown voltage and the width of the p-type regions of the parallel pn layer, in the conventional example. FIG. 10 is a characteristics diagram showing a relationship between conformity rates and the width of the p-type regions of the parallel pn layer, in the example and the conventional example. Results of simulation of multiple sessions, each performed under different conditions for the width Wₚ of the p-type regions 22 of the parallel pn layer 20 with respect to the breakdown voltage of the example described above (refer to FIGS. 6 and 7) are shown in FIG. 8. The set breakdown voltage of the example was 1200 V.

In FIG. 8, a vertical axis indicates breakdown voltage (BV). In FIG. 8, a horizontal axis indicates a ratio ΔWₚ (%) of the increase/decrease from the standard condition (ΔWp=0%) of the width Wₚ of the p-type regions 22 of the parallel pn layer 20, calculated as “ΔWₚ= (the width Wₚ of the p-type regions 22 of the simulation condition - the width Wₚ of the p-type regions 22 of the standard condition)/the width Wₚ of the p-type regions 22 of standard condition”. In FIG. 8, in an instance of ΔWₚ<0% and in an instance of ΔWₚ>0%, the width Wₚ of the p-type regions 22 of the parallel pn layer 20 may be reduced or increased with respect to the width Wₚ of the p-type regions 22 of the parallel pn layer 20 of the standard condition, in either instance.

For comparison, results for the breakdown voltage of the conventional example (refer to FIG. 7) described above are shown in FIG. 9. In other words, FIG. 9 is an instance in which the charge balance of the n-type regions and the p-type regions adjacent to one another in the parallel pn layer is uniformly the standard condition in the depth direction. Here, the standard condition is set as an n-rich condition that the charge balance CB calculated by equation (1) described above is about -15%. The set breakdown voltage and simulation conditions of the conventional example are the same as those for the example. In FIG. 9, a horizontal axis ΔWₚ (%) and a vertical axis BV (V) are the same as the horizontal axis and the vertical axis in FIG. 8. Results of simulation of the conforming rates for the example and the conventional example are shown in FIG. 10.

From the results shown in FIGS. 8 and 9, it was confirmed that, as compared to the conventional example, decreases in the breakdown voltage could be mitigated in the example, when the ratio ΔWₚ of increase/decrease from the standard condition of the width Wₚ of the p-type regions 22 of the parallel pn layer 20 is -20% or more (compare portions surrounded by frames 51, 52 in FIGS. 8 and 9). It was confirmed that like in the example, the charge balance CB of the n-type region 21 and the p-type region 22 that are adjacent to each other in the parallel pn layer 20 has the first and second gradients D₊, D₋ described above, whereby decreases in the breakdown voltage with respect to variation of the width Wₚ of the p-type regions 22 of the parallel pn layer 20 are suppressed and the process margin for dimensional deviation of the width Wₚ of the p-type regions 22 of the parallel pn layer 20 may be increased.

From the results shown in FIG. 10, it was confirmed that in the example, the ratio ΔWₚ of decrease from the standard condition of the width Wₚ of the p-type regions 22 of the parallel pn layer 20 may be set to be in a range of -20% to 10% and the conformity rate may be set to about 80%. It was confirmed that even when the ratio ΔWₚ of decrease from the standard condition of the width Wₚ of the p-type regions 22 of the parallel pn layer 20 is -30%, the conformity rate may be set to be at least twofold as compared to the conventional example. Here, an instance of the breakdown voltage BV being 1200 V or greater and a drain-source current ldss being less than 1 mA was set for a conforming product. An upper limit of the drain-source current Idss is the current value in the instance of a breakdown voltage of 1200 V.

Even in an instance in which the impurity concentration of the n-type buffer region 2a is substantially the same as the impurity concentration of the n-type regions 21 of the parallel pn layer 20 (refer to FIG. 3), results substantially the same as those for the example are obtained.

In the foregoing, the present invention is not limited to the described embodiments and various modifications within a range not departing from the spirit of the invention are possible. For example, without limitation to a MOSFET, the present invention is applicable to a MOS-type semiconductor device such as insulated gate bipolar transistor (IGBT) in which the drift layer is the parallel pn layer. Further, the present invention is similarly implemented when the conductivity types (n-type, p-type) are reversed.

The silicon carbide semiconductor device according to the present invention achieves an effect in that decreases in the breakdown voltage with respect to variation of the width of second-conductivity-type regions of a parallel pn layer may be suppressed.

As described above, the silicon carbide semiconductor device according to the present invention is useful for power semiconductor devices having a SJ structure, used in power converting equipment, power supply devices of various types of industrial machines and is particularly suitable in instances in which the p-type regions of the parallel pn layer are formed by ion implantation when the parallel pn layer is formed using a multistage epitaxial method.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate containing silicon carbide, the semiconductor substrate having a first main surface and a second main surface that are opposite to each other;
a parallel pn layer provided in the semiconductor substrate, the parallel pn layer having therein a plurality of first-conductivity-type regions and a plurality of second-conductivity-type regions disposed adjacent to one another so as to repeatedly alternate with one another in a direction that is parallel to the first main surface of the semiconductor substrate;
a device structure provided between the first main surface and the parallel pn layer;
a first electrode provided on the first main surface and electrically connected to the device structure; and
a second electrode provided on the second main surface of the semiconductor substrate, wherein
the parallel pn layer has a standard portion, a first portion and a second portion, the standard portion being located at a standard depth that is a center of the parallel pn layer in a depth direction or having a range of depth, a center of the range of depth being located at the standard depth, the first portion being located closer to the first main surface than is the standard portion, the second portion being located closer to the second main surface than is the standard portion,
between each adjacent two regions that includes one first-conductivity-type region and one second-conductivity-type region of the parallel pn layer that are adjacent to each other,
in the standard portion, an amount of a first-conductivity-type charge and an amount of a second-conductivity-type charge meet a standard condition,
in the first portion, an amount of the second-conductivity-type charge is greater than an amount of the first-conductivity-type charge,
is greater than an amount of the second-conductivity-type charge in the standard portion, and
continuously increases with a first gradient in a first direction that is the depth direction from the standard portion toward the first main surface,
in the second portion,
an amount of the first-conductivity-type charge is greater than the amount of the second-conductivity-type charge,
an amount of the second-conductivity-type charge
is less than the amount of the second-conductivity-type charge of the standard portion, and
continuously decreases with a second gradient in a second direction that is the depth direction from the standard portion toward the second main surface.

2. The silicon carbide semiconductor device according to claim 1, wherein
an absolute value of the first gradient is greater than an absolute value of the second gradient.

3. The silicon carbide semiconductor device according to claim 1, wherein an equation
$$" \text{CB =} \frac{{Q}_{p} - {Q}_{n}}{{Q}_{n}} \times 100 "$$
is satisfied in the parallel pn layer,
where, “Qₚ = Nₐ × Wₚ” and “Qₙ = N_{d} × Wₙ”,
“Nₐ” and “Wₚ” respectively represent a carrier concentration and a width of the one first-conductivity-type region included in said each adjacent two regions, and
“N_{d}” and “Wₙ” respectively represent a carrier concentration and a width of the one second-conductivity-type region included in said each adjacent two regions,
the CB has an upper limit of +160% in the first portion and a lower limit of 30% in the second portion.

4. The silicon carbide semiconductor device according to claim 1, wherein an equation
$$" \text{CB =} \frac{{Q}_{p} - {Q}_{n}}{{Q}_{n}} \times 100 "$$
and an expression
$$" 5 \leq \left|\frac{{\text{CB1}}_{+}}{{\text{CB1}}_{-}}\right| \leq 6 "$$
are satisfied in the parallel pn layer,
where, “Qₚ = Nₐ × Wₚ” and “Qₙ = N_{d} × Wₙ”,
“Nₐ” and “Wₚ” respectively represent a carrier concentration and a width of the one first-conductivity-type region included in said each adjacent two regions, and
“N_{d}” and “Wₙ” respectively represent a carrier concentration and a width of the one second-conductivity-type region included in said each adjacent two regions,
“CB1₊” corresponds to a CB at a first depth located at a first distance in the first direction away from the standard depth,
“CB1₋” corresponds to a CB at a second depth located at a second distance in the second direction away from the standard depth, and
the first and second distances are the same distance.

5. The silicon carbide semiconductor device according to claim 1, wherein
the standard condition defines amounts of the first-conductivity-type charge and the second-conductivity-type charge in said each adjacent two regions that obtain a greatest breakdown voltage.

6. The silicon carbide semiconductor device according to claim 1, wherein
an impurity concentration of the plurality of first-conductivity-type regions is constant in the depth direction.

7. The silicon carbide semiconductor device according to claim 1, further comprising
a buffer region of the first conductivity type, provided between the second main surface and the parallel pn layer, an impurity concentration of the buffer region being lower than an impurity concentration of the plurality of first-conductivity-type regions, wherein
a first interface between the buffer region and the plurality of first-conductivity-type regions is located closer to the first main surface than is a second interface between the buffer region and the plurality of second-conductivity-type regions, and
a difference of amounts between the first-conductivity-type charge and the second-conductivity-type charge in said each adjacent two regions at a depth of the first interface is minimum in the pn parallel layer.

8. The silicon carbide semiconductor device according to claim 7, wherein
the second portion includes a third portion between the first interface and the second interface, and
amounts of the first-conductivity-type charge and the second-conductivity-type charge in said each adjacent two regions in the third portion are constant in the depth direction.

9. The silicon carbide semiconductor device according to claim 8, wherein an equation
$$" \text{CB =} \frac{{Q}_{p} - {Q}_{n}}{{Q}_{n}} \times 100 "$$
and an expression
$$" 5 \leq \left|\frac{{\text{CB2}}_{+}}{{\text{CB2}}_{-}}\right| \leq 20 "$$
are satisfied in the parallel pn layer,
where “Qₚ = Nₐ × Wₚ” and “Qₙ = N_{d} × Wₙ”,
“Nₐ” and “Wₚ” respectively represent a carrier concentration and a width of the one first-conductivity-type region included in said each adjacent two regions, and
“N_{d}” and “Wₙ” respectively represent a carrier concentration and a width of the one second-conductivity-type region included in said each adjacent two regions,
“CB2₊” represents CB at a third depth located at a third distance in the second direction away from a surface of the parallel pn layer that faces the first main surface,
“CB2₋” represents CB at a fourth depth located a fourth distance in the first direction away from the second interface, and
the third and fourth distances are the same distance.

10. The silicon carbide semiconductor device according to claim 8, wherein
the impurity concentration of the plurality of first-conductivity-type of the pn parallel layer is constant in the depth direction.

11. The silicon carbide semiconductor device according to claim 7, wherein
in the second portion, the amount of the second-conductivity-type charge in said each adjacent two regions
continuously decreases with the second gradient in the second direction from the standard portion to the first interface, and
continuously increases with a third gradient in the second direction from the first interface to the second interface.

12. The silicon carbide semiconductor device according to claim 11, wherein an equation
$$" \text{CB =} \frac{{Q}_{p} - {Q}_{n}}{{Q}_{n}} \times 100 "$$
and an expression
$$" 5 \leq \left|\frac{{\text{CB2}}_{+}}{{\text{CB2}}_{-}}\right| \leq 20 "$$
are satisfied in the parallel pn layer,
where “Qₚ = Nₐ × Wₚ” and “Qₙ = N_{d} × Wₙ”,
“Nₐ” and “Wₚ” respectively represent a carrier concentration and a width of the one first-conductivity-type region included in said each adjacent two regions, and
“N_{d}” and “Wₙ” respectively represent a carrier concentration and a width of the one second-conductivity-type region included in said each adjacent two regions,
“CB2₊” represents CB at a third depth located at a third distance in the second direction away from a surface of the parallel pn layer that faces the first main surface,
“CB2₋” represents CB at a fourth depth located a fourth distance in the first direction away from the second interface, and
the third and fourth distances are the same distance.

13. The silicon carbide semiconductor device according to claim 11, wherein
the impurity concentration of the plurality of first-conductivity-type regions is constant in the first direction.

14. A method of manufacturing the silicon carbide semiconductor device according to claim 10, the method comprising:
a multistage epitaxial process of dividing epitaxial growth of a first-conductivity-type epitaxial layer into a plurality of stages and in each of a plurality of sublayers constituting the first-conductivity-type epitaxial layer, formed at the plurality of stages, respectively, ion-implanting a second-conductivity-type impurity, thereby forming a plurality of second-conductivity-type diffused regions constituting the plurality of second-conductivity-type regions, and leaving, as the plurality of first-conductivity-type regions, portions of said sublayer, excluding the plurality of second-conductivity-type diffused regions, thereby forming the parallel pn layer; and
forming the plurality of second-conductivity-type diffused regions having a different impurity concentration in each sublayer of the first-conductivity-type epitaxial layer so that the plurality of second-conductivity-type regions of the parallel pn layer has the impurity concentration distribution.

15. The method according to claim 14, wherein
in the multistage epitaxial process, a lowermost one of the plurality of sublayers constituting the first-conductivity-type epitaxial layer is epitaxially grown having the impurity concentration of the buffer region, and leaving as the buffer region, a portion of the lowermost one of the plurality of sublayers, excluding the plurality of second-conductivity-type diffused regions.

16. A method of manufacturing the silicon carbide semiconductor device according to claim 13, the method comprising:
a multistage epitaxial process of dividing epitaxial growth of a first-conductivity-type epitaxial layer into a plurality of stages and in each of a plurality of sublayers constituting the first-conductivity-type epitaxial layer, formed at the plurality of stages, respectively, ion-implanting a second-conductivity-type impurity, thereby, forming a plurality of second-conductivity-type diffused regions constituting the plurality of second-conductivity-type regions, and leaving, as the plurality of first-conductivity-type regions, portions of said sublayer, excluding the plurality of second-conductivity-type diffused regions, thereby forming the parallel pn layer; and
forming the plurality of second-conductivity-type diffused regions having a different impurity concentration in each sublayer of the first-conductivity-type epitaxial layer so that the plurality of second-conductivity-type regions of the parallel pn layer has the impurity concentration distribution.

17. The method according to claim 16, wherein
in the multistage epitaxial process, a lowermost one of the plurality of sublayers constituting the first-conductivity-type epitaxial layer is epitaxially grown having the impurity concentration of the buffer region, and leaving as the buffer region, a portion of the lowermost one of the plurality of sublayers, excluding the plurality of second-conductivity-type diffused regions.

18. A method of manufacturing the silicon carbide semiconductor device according to claim 10, the method comprising:
a trench embedding epitaxial method of forming the parallel pn layer, including:
epitaxially growing a first-conductivity-type epitaxial layer;
forming a plurality of trenches in the first-conductivity-type epitaxial layer, and leaving in the first-conductivity-type epitaxial layer, portions thereof constituting the plurality of first-conductivity-type regions; and
embedding in the trenches, a second-conductivity-type epitaxial layer that constitutes the plurality of second-conductivity-type regions, wherein
during epitaxial growth of the second-conductivity-type epitaxial layer, an impurity concentration thereof is varied, inducing the plurality of second-conductivity-type regions of the parallel pn layer to have the impurity concentration distribution.

19. The method according to claim 18, wherein
forming the first-conductivity-type epitaxial layer includes sequentially forming, by epitaxial growth, a first-conductivity-type layer having an impurity concentration that is a same as the impurity concentration of the buffer region and a second-conductivity-type layer having an impurity concentration that is a same as the impurity concentration of the plurality of first-conductivity-type regions, and
the trenches are formed terminating in the first-conductivity-type layer, and in the first-conductivity-type epitaxial layer, portions are left constituting the buffer region and the plurality of first-conductivity-type regions.

20. A method of manufacturing the silicon carbide semiconductor device according to claim 13, the method comprising:
a trench embedding epitaxial method of forming the parallel pn layer, including:
epitaxially growing a first-conductivity-type epitaxial layer;
forming a plurality of trenches in the first-conductivity-type epitaxial layer, and leaving in the first-conductivity-type epitaxial layer, portions thereof constituting the plurality of first-conductivity-type regions; and
embedding in the trenches, a second-conductivity-type epitaxial layer that constitutes the plurality of second-conductivity-type regions, wherein
during epitaxial growth of the second-conductivity-type epitaxial layer, an impurity concentration thereof is varied, inducing the plurality of second-conductivity-type regions of the parallel pn layer to have the impurity concentration distribution.

21. The method according to claim 20, wherein
forming the first-conductivity-type epitaxial layer includes sequentially forming, by epitaxial growth, a first-conductivity-type layer having an impurity concentration that is a same as the impurity concentration of the buffer region and a second-conductivity-type layer having an impurity concentration that is a same as the impurity concentration of the plurality of first-conductivity-type regions, and
the trenches are formed terminating in the first-conductivity-type layer, and in the first-conductivity-type epitaxial layer, portions are left constituting the buffer region and the plurality of first-conductivity-type regions.
